(19) United States
(12) Patent Application Publication
(10) Pub. No.: US 2020/0126892 A1
(43) Pub. Date: Apr. 23, 2020

(54) High Efficiency Thermal Management Device for Use With Components Having High Heat Flux Values

(71) Applicant: The California State University - Northridge, Northridge, CA (US)

(72) Inventors: Shadi Mahjoob, Northridge, CA (US); Carlos Zing, Northridge, CA (US)

(73) Assignee: The California State University - Northridge, Northridge, CA (US)

(21) Appl. No.: 16/423,901

(22) Filed: May 28, 2019

Related U.S. Application Data
(60) Provisional application No. 62/677,094, filed on May 28, 2018.

(51) Int. Cl. H01L 23/473; H01L 23/367

(52) U.S. Cl. CPC H01L 23/4735; H01L 23/3675

(57) ABSTRACT

High efficiency heat management devices for use with a component, are disclosed and include: at least one porous filled channel configuration component or at least one foam filled channel configuration component, wherein the at least one porous filled channel configuration component or at least one foam filled channel configuration component comprises a channel base and a surface; at least one jet impingement of at least one thermal management liquid or gas; at least one jet inlet, wherein the at least one jet inlet directs the at least one jet impingement of a liquid or a gas onto the surface of the at least one porous filled channel configuration component or at least one foam filled channel configuration component; and at least one thermal management liquid or gas exit channel.

This United States Utility application claims priority to U.S. Provisional Patent Application Ser. No. 62/677,094, which is entitled “Thermal Transport in Confined Single and Multiple Jet Impingements Through Porous Filled Non-Uniform Cross Section Channels”, which was filed on May 28, 2018, and which is commonly-owned and incorporated by reference herein in its entirety.

### FIELD OF THE SUBJECT MATTER

The field of the subject matter is high efficiency or highly efficient thermal or heat management devices for the purpose of cooling of components that have high heat flux values or heating components that need to be heated.

### BACKGROUND

The transistor, in essence an electronic on/off switch and the main component to microprocessors, has birthed the electronic age, allowing electronics to tunnel into almost every aspect of modern life, from toys and cellular phones to air and space craft. Because the number of transistors correlates directly to electronic performance, humans have been trying to increase the density in each processor by making smaller and smaller transistors.

A microprocessor during the 70's would have a transistor count in the thousands, today, they are found with a count above 2 billion. A processor is made up of different electrical components; resistors, capacitors, transistors, etc., and every component provides an electrical resistance to some degree, resulting in a rise in temperature and/or heat loss. Partly because of Moore's law, a demand for smaller components, and higher processing speeds, the heat flux and, consequently, the temperature in electronic components is predicted to climb even higher. As such, electronic components may break down when operating for long periods of time at high temperatures, and the failure rate increases exponentially with the operating temperature [1]. That indicates the importance of cooling of electronic devices. Some of the main cooling techniques include indirect liquid cooling, natural convection plus radiation, forced air convection, and immersion cooling.

Utilization of porous inserts can enhance cooling effectiveness and temperature control by providing a large surface area for a given volume. Metal foam is a type of porous material with a system of interconnected metal filaments. At its basic unit, it is a polyhedron with twelve to fourteen hexagon or pentagon faces [2]. The metal foam tortuosity provides mixing of the fluid passing through the foam and so improves heat transfer and temperature uniformity. The foam can be described by its porosity, filament thickness, permeability, pore diameter, and pore density. A reduction in pore size or porosity or an increase in pore density or flow's Reynold's number would result in higher heat transfer and pressure drop. Therefore, a compromise between the heat transfer rate and pressure drop should be made. Metal foams can be employed for advanced cooling systems. For instance, metal foam can be used to increase performance of heat sinks, by utilizing cooling through natural convection [17], applying metal foam between layers of finned heat sinks [18], and jet impingement through metal foam with a restricted outlet [19]. Several effective thermal conductivity models have been introduced in literature based on arranged thermal resistances for fluid and solid phases in series, parallel, or their variations. Bhattacharya et al. [20] developed a theoretical model using a two-dimensional hexagon with circular blobs of metal to represent a unit of metal foam. Yang et al. [21] presented an analytical model based on a tetradecahedron with cuboid nodes as its representative unit cell. Iasiello et al. [22] developed a model that takes into account a metal foams anisotropy, which comes from elongations of filaments in one direction occurring during manufacturing. Ranut [23] studied different effective thermal conductivity models while categorizing the models as asymptotic, empirical, or analytical approaches. More details on thermal transport in porous material can be found in the following references: [2, 14, 24-27].

Jet impingement on the other hand, has also been established to achieve high heat transfer rates. Since its discovery, it has been used in applications such as annealing sheet metal and cooling of lasers, turbine blades, and electronic equipment. An impinging jet's geometry is typically a nozzle facing a flat surface a distance away. Fluid exits the nozzle at a certain velocity, developing into a free jet, until it enters a stagnation zone where it starts decelerating due to the flat plate's presence, and starts accelerating away from the origin, parallel and adjacent to the plate, developing into wall jets. Bintoro et al. [3] numerically and experimentally studied a closed loop, single impinging jet heat exchanger system designed for electronic cooling, for the range of 10,000 to 31,000 Reynold's number. They forced water through two different diameter nozzles, 0.5 and 0.8 mm, to impinge on the face of a 12 mm diameter copper cylinder, 13 mm away. Bintoro et al. [3] declared that the system was able to keep a computer chip generating a maximum heat of 200 Watts under safe working conditions. While examining different nozzles, they concluded that a larger nozzle would provide a larger heat transfer for the same Reynold's number in this system. Regarding the effect of Reynold's number, a larger Reynold's number results in a higher convection heat transfer coefficient. Other jet impinging geometries commonly studied are jet arrays, in which, multiple jets impinge on a flat surface. Iyengar and Ellsworth [4] numerically investigated the effect of a range of impinging water jets, 1, 16, and 36, on a computer chip 0.5 mm away, utilizing two different outlet schemes. In one of the schemes, the outlet was found on the periphery of the chip, where the fluid flows perpendicular to the impinging jet. In the other scheme, the outlets were holes with twice the diameter as the inlet jets, found in the same plane and between the inlet jet orifices, where the fluid outflow would flow parallel to the impinging jets. They concluded that regardless of outlet scheme, for cases of the same volumetric flow rate, more impinging jets would result in significantly better effective heat transfer and more uniform temperature distribution on chip surface. Increasing the volumetric flow rate has similar effects. The comparison of the two outlet schemes indicates that, due to separation sections, a considerably higher heat transfer rate for all periphery outlet cases are obtained than that of their parallel outlet opposites [4].

Thermal transport through four different porous filled configurations, namely confined or unconfined with totally filled or partially filled porous materials, is discussed in [5]. Confined/unconfined geometries refer to whether flow through porous substrate is bounded by the channel walls (confined) or not (unconfined). Totally/completely filled or partially filled refers to the porous media and whether it encompasses every space through which the fluid flows. Partially filled cases usually have thin porous blocks adjacent to the base surface. Sivasamy et al. [6] numerically investigated cooling of a totally filled, confined parallel channel, subjected to a constant heat flux, utilizing a single jet. The effects of varying the nozzle diameter, Peclet number, Rayleigh number, and jet exit to heated surface distance are studied. The results indicate that at high Peclet numbers, where impinging jet forces overcome buoyancy forces, the Rayleigh number has negligible effect on the thermal transport. Also increasing the inlet diameter or decreasing jet-heated surface distance would improve overall heat transfer for cases of high Peclet number. Similar works confirm the above conclusions [7-8]. Rallabandi et al. [9] experimentally investigated high pressure air impinging through multiple inlet jets on a partially filled, confined parallel channel subjected to a uniform heat flux. Their results show a significant increase in heat transport for the porous foam with coating compared with similar case without the coating.

It is shown that utilization of nanofluids may improve thermal transport and efficiencies in heat management devices [28-30]. Diameter sizes of suspended particles in nanofluids range in nanometers leading to low corrosion probability. Zing et al.[29] numerically analyzed single jet impingement through a confined totally porous filled channel subject to a high uniform heat flux of 10⁶ W/m² at the channel's base. They investigated the effects of porosity, porous material, and coolants (water, 5% titanium dioxide (TiO₂) in water, 1% alumina in water, 1% diamond in 40:60 ethylene glycol/water, and 0.03% multi walled carbon nanotubes (MWCNT) in water). The results indicate that utilization of 5% titanium dioxide (TiO₂) in water nanofluid improves cooling efficiency and temperature uniformity over the channel's base.

For modeling heat transfer through porous media, volume averaged equations are commonly employed in which the transport equations are integrated over an elementary volume. There are two approaches to develop volume averaged energy equations. One is based on averaging over a representative elementary volume containing both fluid and solid phases and applying the assumption of local thermal equilibrium (referred to as one equation model). The other approach is to average over each of the phases separately and applying the assumption of local thermal non-equilibrium, resulting in energy equations for each individual phase (referred to as two equation model) [31]. If there is a large temperature difference between fluid and solid at the interface of the phases, the interfacial surface area and interstitial heat transfer coefficient will become key factors affecting the internal heat transfer between the phases. The product of these two variables is referred to as the volumetric heat transfer coefficient [32], thus a low volumetric heat transfer coefficient corresponds to a high temperature difference between phases. That is when the employment of two-equation model would be crucial [31, 33].

Therefore, it is desirable and ideal to develop innovative high efficiency or highly efficient heat or thermal management devices for cooling components that have high heat flux values. Contemplated ideal devices would have a number of geometrical parameters, such as location and size of jet inlet channels, orientation of ceiling confining wall, flow rate in each channel, and heat fluxes. Contemplated devices should have several applications, including but not limited to, electronics cooling and cooling of biomedical devices, cooling of powered electrical equipment such as x-rays, lasers, ultrasound equipment, radiography machines, surgical equipment, and solar radiation receivers [10-11].

### SUMMARY OF THE SUBJECT MATTER

High efficiency heat management devices for cooling a component, are disclosed and include: at least one porous filled or foam filled channel configuration component, wherein the at least one porous filled channel configuration component comprises a channel base and a surface; at least one jet impingement of at least one coolant; at least one jet inlet, wherein the at least one jet inlet directs the at least one jet impingement of a liquid or a gas onto the surface of the at least one porous filled channel configuration component; and at least one coolant exit channel.

In addition, high efficiency heat management devices for use with a component, are disclosed and include: at least one porous filled channel configuration component or at least one foam filled channel configuration component, wherein the at least one porous filled channel configuration component or at least one foam filled channel configuration component comprises a channel base and a surface; at least one jet impingement of at least one thermal management liquid or gas; at least one jet inlet, wherein the at least one jet inlet directs the at least one jet impingement of a liquid or a gas onto the surface of the at least one porous filled channel configuration component or at least one foam filled channel configuration component; and at least one thermal management liquid or gas exit channel.

### BRIEF DESCRIPTION OF THE FIGURES

FIG. 1A-D shows schematic diagrams (a) front view of single jet impingement, (b) front view of multi jet impingements, (c) a three-dimensional case with single rectangular cross-section inlet channel, and (d) a three-dimensional case with multi square cross-section inlet channels.

FIG. 2A-B shows non-dimensional base temperature profiles along the streamwise direction for grid independence study (a) Case C3d and (b) Case N3d.

FIG. 3A-B shows a comparison of current numerical study with analytical data for flow through a uniform confined porous filled or foam filled channel (a) schematic diagram of the channel (b) non-dimensional solid and fluid temperature profiles

### at Bi=10, ε=0.1, κ=0.11 for Φ=0 and 1.

FIG. 4A-C shows non-dimensional base temperature for investigated two dimensional cases defined in Table 1 (a) set 1 (b) set 2 (c) set 3.

FIG. 5 shows non-dimensional temperature distribution along streamwise direction for channels with and without inclined walls.

FIG. 6A-B shows non-dimensional temperature profiles across the base for investigated three dimensional single and multi-inlet cases A3d-O3d (a) along streamwise direction and (b) along transverse direction.

FIG. 7 shows non-dimensional temperature contours across the base of cases A3d-O3d.

FIG. 8A-C shows non-dimensional fluid and solid temperature profiles for cases A3d and C3d with porosity values of 0.45 and 0.9 (a) X=0, (b) X=0.5, and (c) X=1.

FIG. 9A-C shows non-dimensional base temperature along streamwise direction (a) cases A3d and C3d with water and TiO₂ coolants and ε=0.45, (b) cases A3d and C3d with water and TiO₂ coolants and ε=0.9, and (c) cases B3d, D3d, G3d, H3d, L3d, M3d, N3d, and O3d with Tio2 coolant and ε=0.45.

FIG. 10A-B shows a comparison of the non-dimensional velocity and temperature profiles in a porous filled channel with those of an analytical solution by Vafai and Kim at Da^{-1/2} and Λ=10, 100 (a) non-dimensional velocity, (b) non-dimensional temperature.

FIG. 11A-B shows non-dimensional temperature profile comparisons for grid independence study of the investigated geometries with a porosity of 0.45 for (a) rectangular and (b) square cross-sectional inlet channels, subject to a uniform heat flux of 10⁶ W/m².

FIG. 12 shows non-dimensional temperature distribution along the streamwise direction on the base centerline of the cases with the inclination angles of 5.96° and 13.74° and parallel channel walls.

FIG. 13 shows non-dimensional temperature distribution along the streamwise direction on the base centerline for different inlet velocities.

FIG. 14A-B shows non-dimensional temperature distribution along the streamwise direction on the base centerline for different wall base surface heat flux values. Temperature values are non-dimensional using (a) a heat flux of 10⁶ W/m² or (b) corresponding heat flux.

FIG. 15A-C shows non-dimensional temperature distribution along the streamwise direction on the base centerline, for rectangular (Rect.) and square (Sq.) cross-sectional inlet channels, for different coolants (a) Copper porous insert with a porosity of 45%, (b) APG porous insert with a porosity of 45%, and (c) APG porous insert with a porosity of 90%.

FIG. 16A-C shows non-dimensional temperature distribution along the transverse direction on the base centerline, for rectangular (Rect.) and square (Sq.) cross-sectional inlet channels, for different coolants (a) Copper porous insert with a porosity of 45%, (b) APG porous insert with a porosity of 45%, and (c) APG porous insert with a porosity of 90%.

### DETAILED DESCRIPTION

Innovative high efficiency or highly efficient heat or thermal management devices for cooling components that have high heat flux values have been developed and are disclosed herein. Contemplated devices have a number of geometrical parameters, such as location and size of jet inlet channels, orientation of ceiling confining wall, flow rate in each channel, and heat fluxes. Contemplated devices have several applications, including but not limited to, electronics cooling or thermal management, thermal management and/or cooling of biomedical devices, and thermal management and/or cooling of powered electrical equipment, such as x-rays, lasers, ultrasound equipment, radiography machines, surgical equipment, and solar radiation receivers.

Cooling of electronics devices is one of the main issues in development of advanced devices such as electronics and biomedical devices. In this work, several multiple jet inlet porous filled heat exchangers are numerically modeled to investigate the thermal performance of different geometrical parameters, such as the thickness of jet impingement inlets, and their location. The importance of the inclined wall is also examined. Utilizing the inclined walls and narrowing the porous filled channels would improve the temperature uniformity.

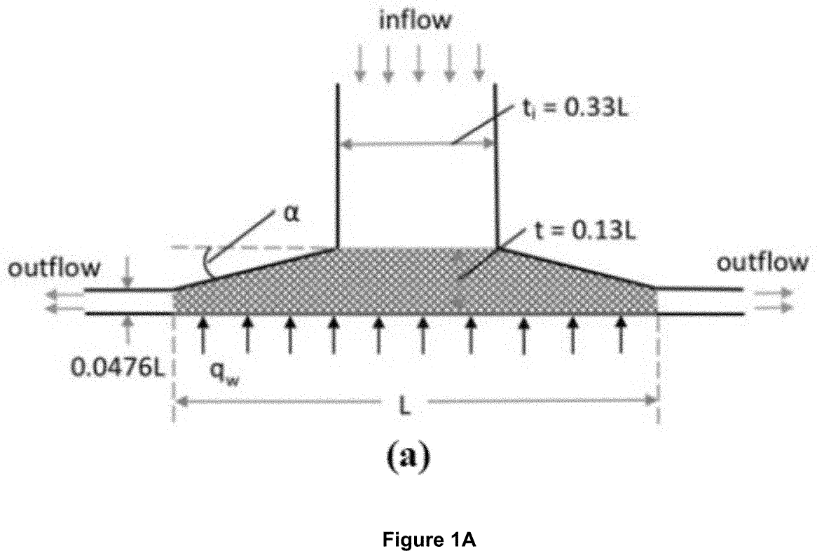

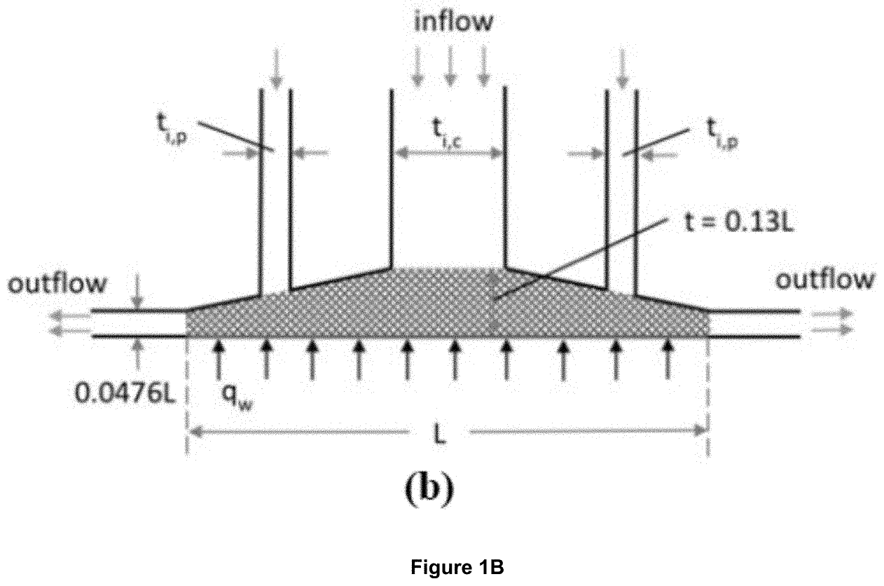

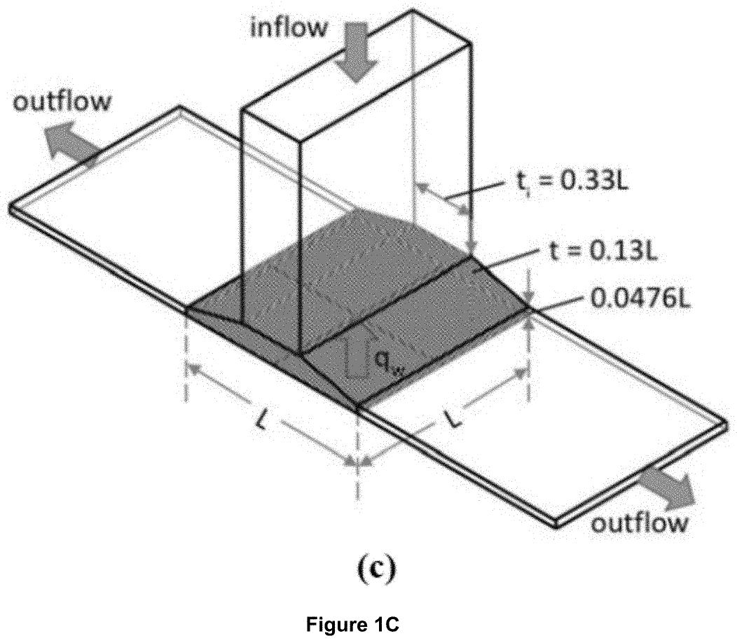

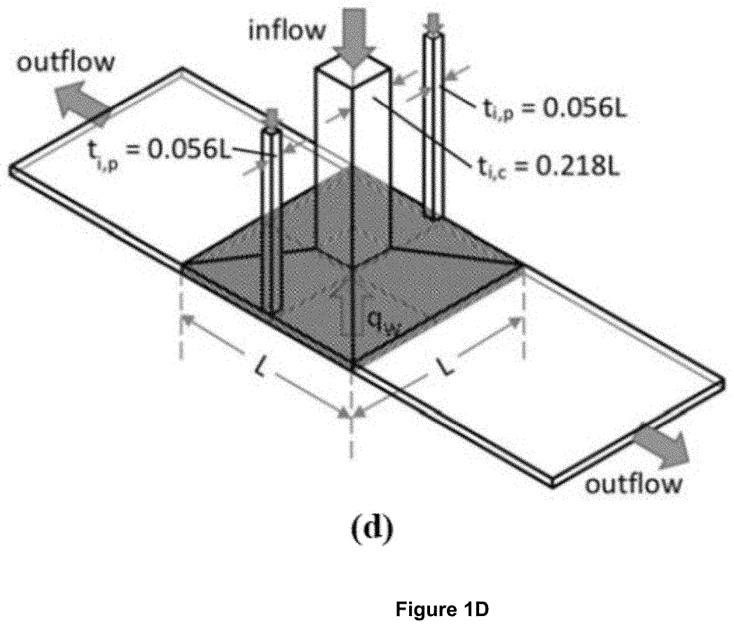

Innovative and contemplated heat exchangers utilizing single and multiple jet impingements are numerically investigated. The heat exchangers are confined non-uniform (with inclined walls) porous filled channels or foam filled channels subjected to uniform heat flux leaving the devices to be cooled. Schematic diagrams of the single jet and one of the multiple jet heat exchangers are presented in FIG. 1. To investigate the effects of the third direction on the results, numerical modeling is performed for both two and three-dimensional configurations.

Specifically, high efficiency heat management devices for use with a component, are disclosed and include: at least one porous filled channel configuration component or at least one foam filled channel configuration component, wherein the at least one porous filled channel configuration component or at least one foam filled channel configuration component comprises a channel base and a surface; at least one jet impingement of at least one coolant; at least one jet inlet, wherein the at least one jet inlet directs the at least one jet impingement of a liquid or a gas onto the surface of the at least one porous filled channel configuration component or at least one foam filled channel configuration component; and at least one coolant exit channel. In some embodiments, components that need to be cooled are cooled, but in other contemplated embodiments, components that need to be heated may be heated by the thermal management devices disclosed herein.

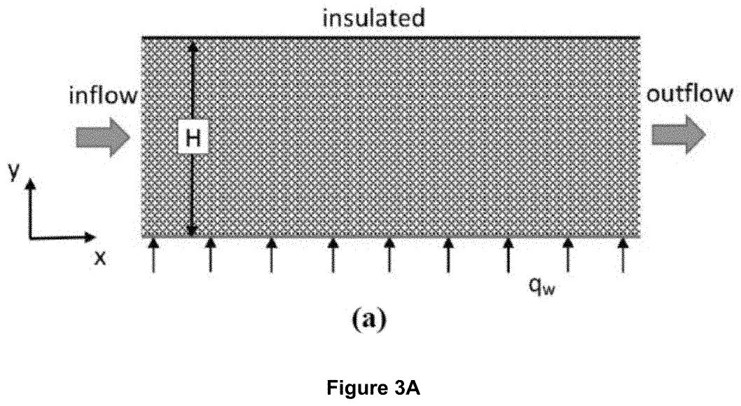

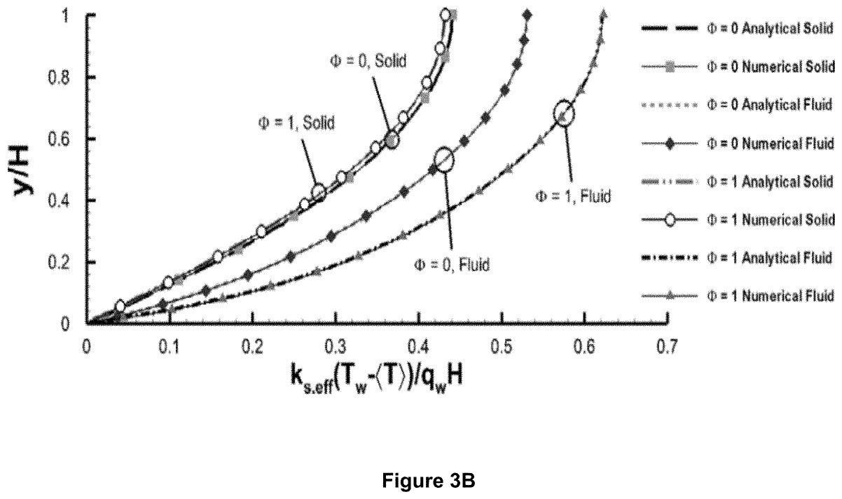

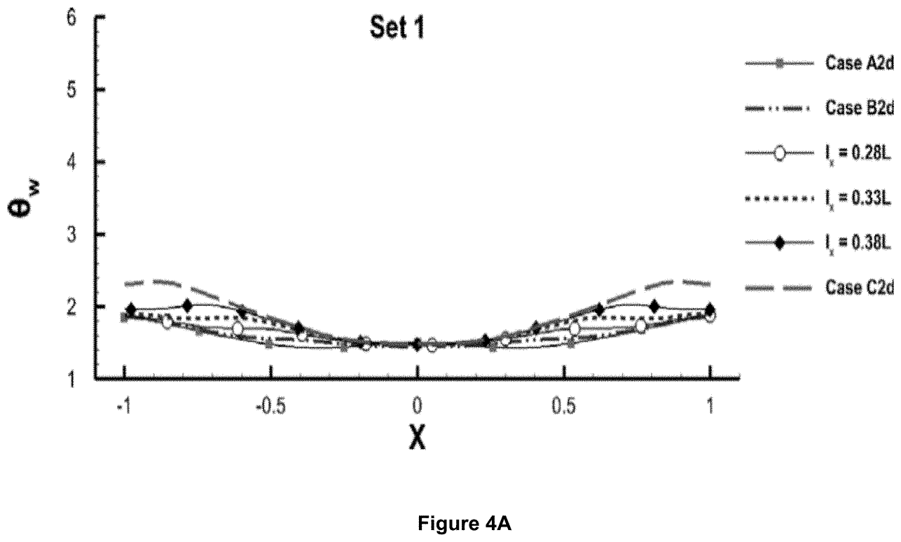

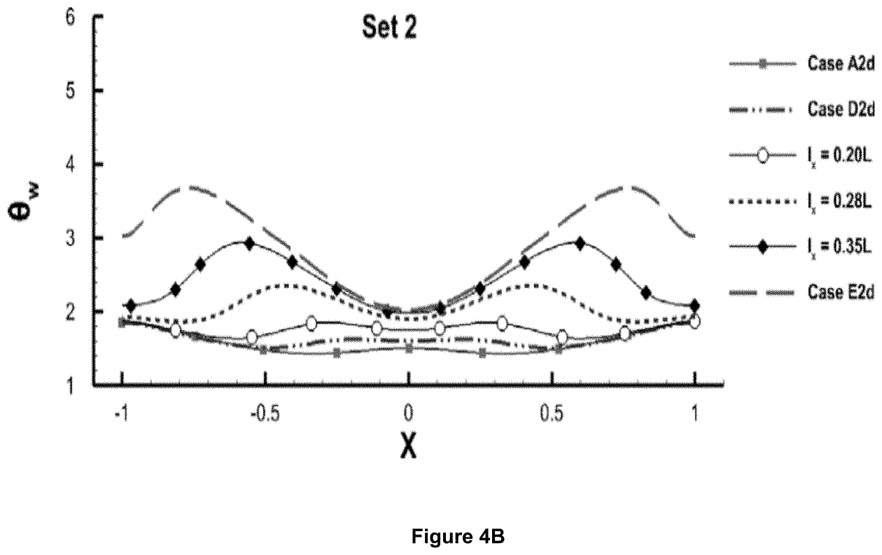

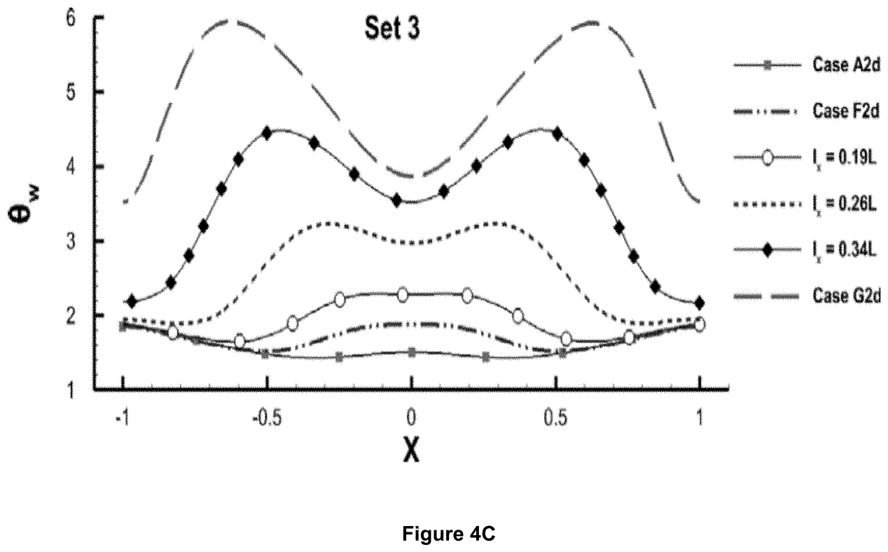

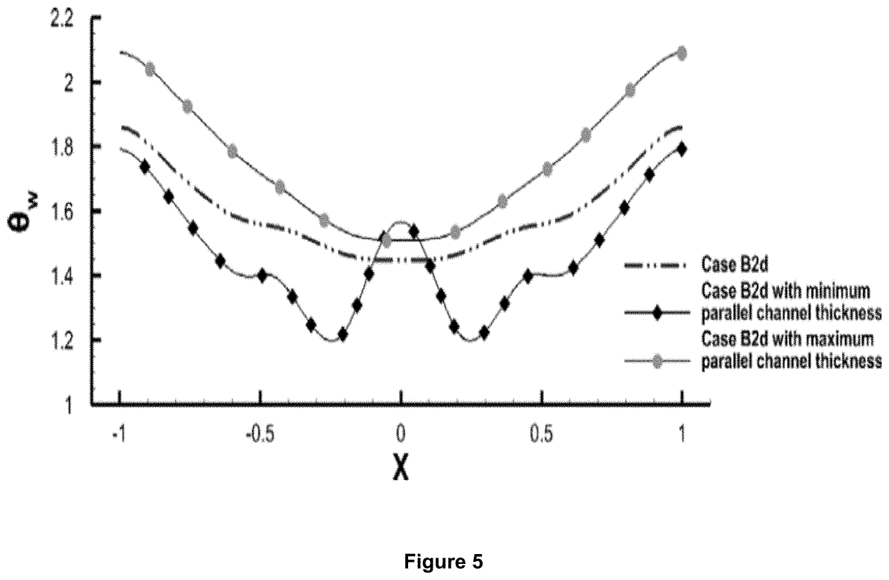

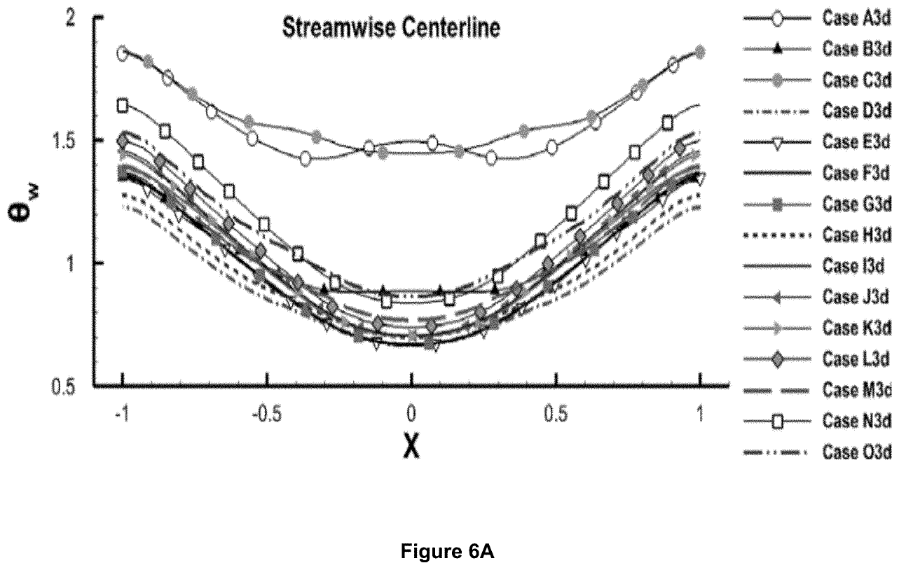

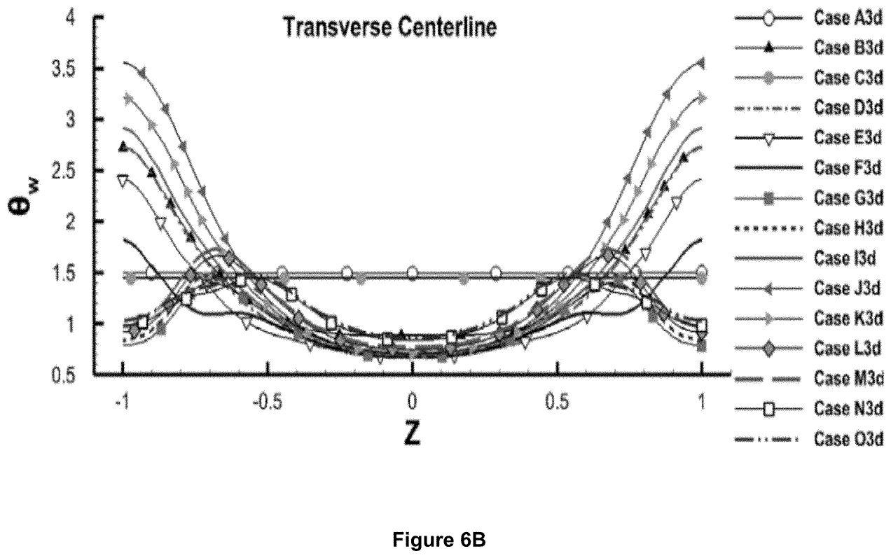

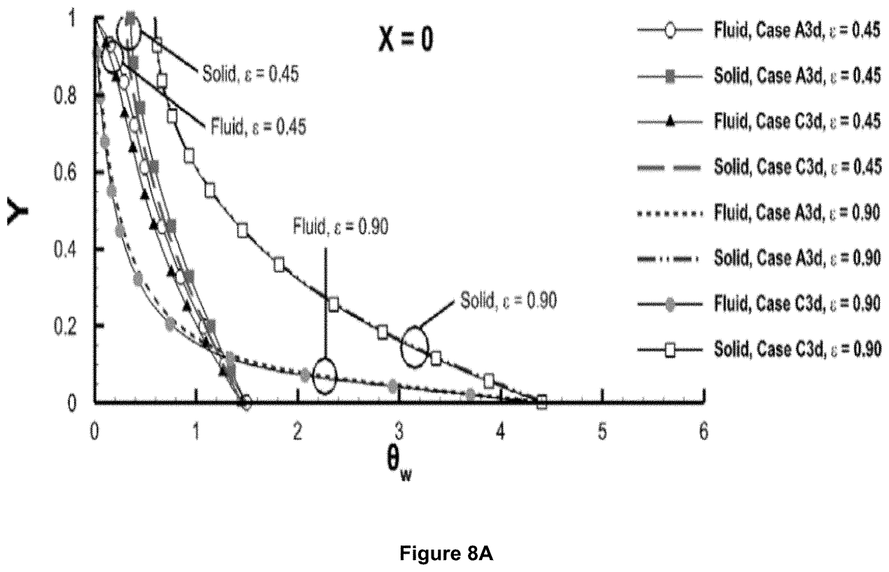

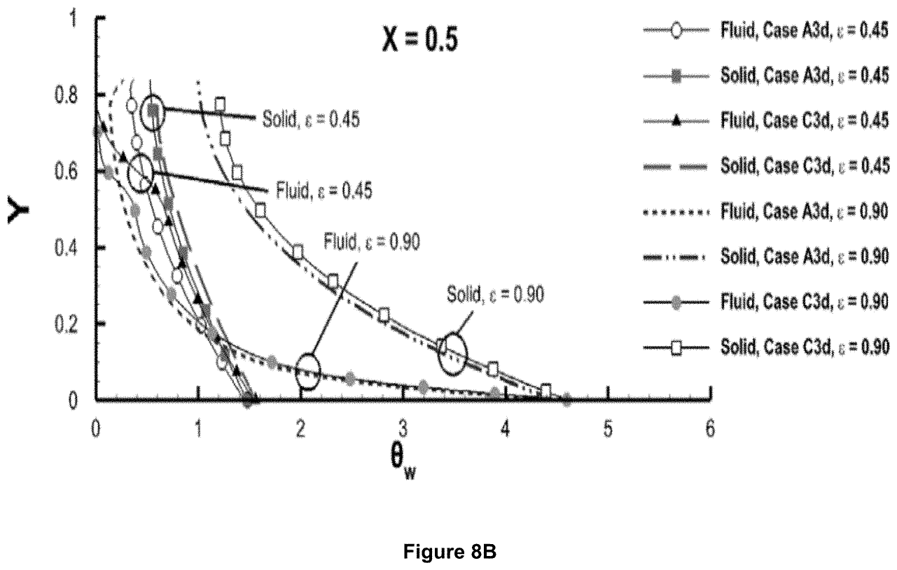

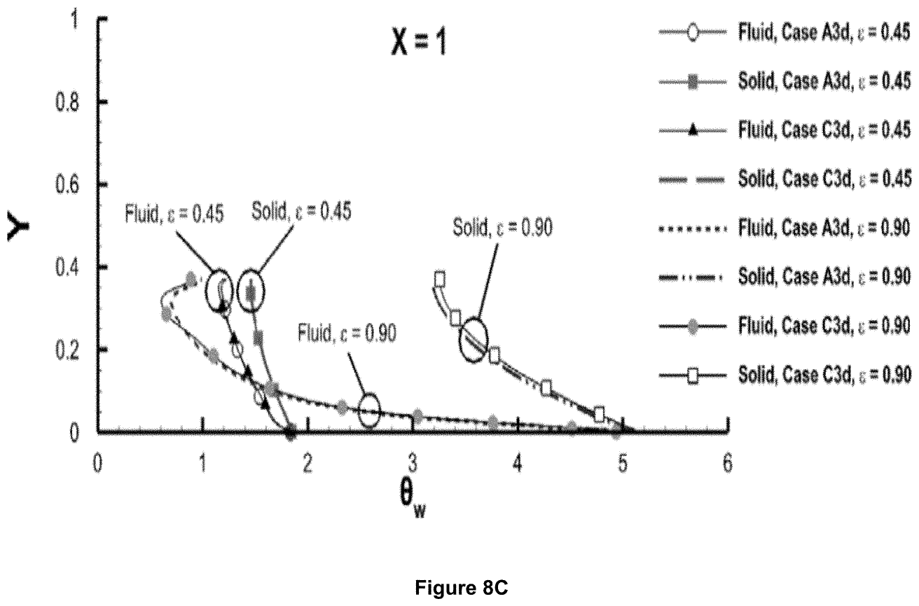

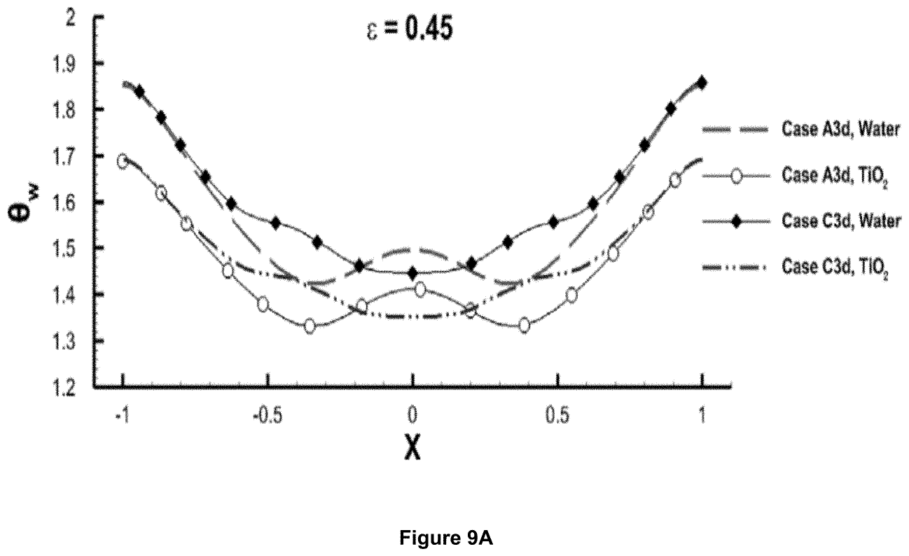

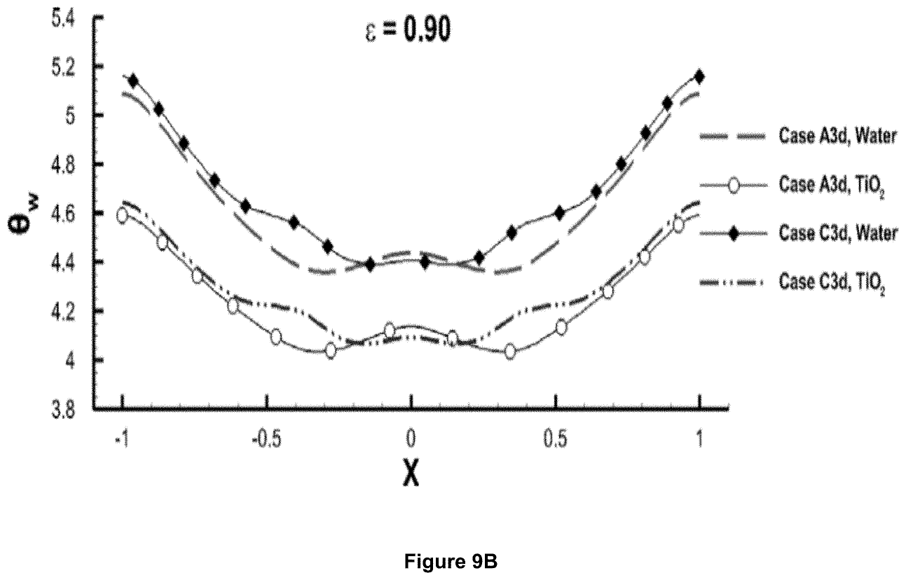

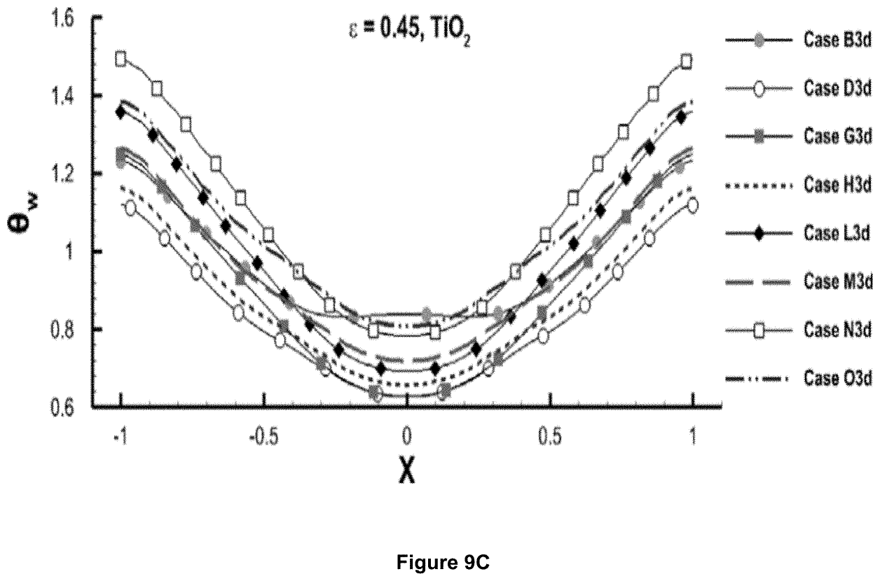

As used herein, the phrases “at least one porous filled channel configuration component” or “at least one foam filled channel configuration component” means that the components are configured to have channels that are either filled with porous materials or foam materials, such as the one shown in FIG. 3A, wherein the channel configuration component shown has a surface and a channel base. These contemplated components can be filled or infused with thermal management solutions, coolants, gases, or another suitable gas or liquid that can provide a degree of thermal management to the subject at least one component having a high heat flux value or the at least one component that requires thermal management.

As mentioned, contemplated devices include at least one porous filled channel configuration component or at least one foam filled channel configuration component. As mentioned earlier, utilization of porous inserts/components or foam inserts/components can enhance cooling effectiveness and temperature control by providing a large surface area for a given volume. Metal foam is a type of porous material with a system of interconnected metal filaments. At its basic unit, it is a polyhedron with twelve to fourteen hexagon or pentagon faces [2]. The metal foam tortuosity provides mixing of the fluid passing through the foam or pores and so improves heat transfer and temperature uniformity. The foam or porous material can be described by its porosity, filament thickness, permeability, pore diameter, and pore density. A reduction in pore size or porosity or an increase in pore density or flow's Reynold's number would result in higher heat transfer and pressure drop. Therefore, a compromise between the heat transfer rate and pressure drop should be made. Metal foams can be employed for advanced cooling systems. For instance, metal foam can be used to increase performance of heat sinks, by utilizing cooling through natural convection [17], applying metal foam or metal porous material between layers of finned heat sinks [18], and jet impingement through metal foam with a restricted outlet [19].

Contemplated metal foams may comprise any suitable metal, combination of metals, or metal-like composite material. A contemplated metal includes aluminum, palladium, platinum, nickel, titanium, osmium, or combinations thereof. One characteristic of contemplated metal foams is that they have a relatively high porosity—which may be defined as 5-25% of the volume of the base metal. Contemplated composite materials, such as aluminum polymers, ceramics, or other suitable composite materials may also be used.

As mentioned earlier, contemplated devices provide thermal transport through four different porous filled configurations, namely confined or unconfined with totally filled or partially filled porous materials. Confined/unconfined geometries refer to whether flow through porous substrate is bounded by the channel walls (confined) or not (unconfined). Totally/completely filled or partially filled refers to the porous media and whether it encompasses every space through which the fluid flows. Partially filled cases usually have thin porous blocks adjacent to the base surface.

Contemplated high efficiency heat management devices for use with a component comprise at least one porous filled channel configuration component or at least one foam filled channel configuration component that is at least partially filled. In some embodiments, contemplated high efficiency heat management devices for use with a component include at least one porous filled channel configuration component or at least one foam filled channel configuration component that is completely filled.

Contemplated high efficiency heat management devices for use with a component include at least one porous filled channel configuration component or at least one foam filled channel configuration component that comprises a confined geometry. In other embodiments, contemplated high efficiency heat management devices for use with a component include at least one porous filled channel configuration component or at least one foam filled channel configuration component that comprises an unconfined geometry.

In addition, high efficiency heat management devices for use with a component, are disclosed and include: at least one porous filled channel configuration component or at least one foam filled channel configuration component, wherein the at least one porous filled channel configuration component or at least one foam filled channel configuration component comprises a channel base and a surface; at least one jet impingement of at least one thermal management liquid or gas; at least one jet inlet, wherein the at least one jet inlet directs the at least one jet impingement of a liquid or a gas onto the surface of the at least one porous filled channel configuration component or at least one foam filled channel configuration component; and at least one thermal management liquid or gas exit channel.

Contemplated thermal management liquids or gases may be any suitable liquid or gas or mixture of liquids or gases that effectively manages the thermal issues that come with use of electronics, biomedical devices, and powered electrical equipment, such as x-rays, lasers, ultrasound equipment, radiography machines, surgical equipment, and solar radiation receivers. Contemplated thermal management liquids or gases may be coolants or may be designed to provide heat to these components, if they are used in areas where the components are subjected to undesirable cooling, such that they cannot properly function. Thermal management liquids may be or comprise nanofluids, which are fluids that have suspensions of ultrafine solid nanoparticles, such as copper oxide, aluminum oxide, titanium dioxide, or combinations thereof. Thermal management liquids may also comprise water, deionized water, waterless coolants, glycols, such as ethylene glycol or propylene glycol, oils, liquid hydrogen, dielectric fluids, or combinations thereof.

Contemplated thermal management gases may comprise air, hydrogen, inert gases, sulfur hexafluoride, steam, liquid gases, such as carbon dioxide, liquid nitrogen, liquid hydrogen. or other suitable gases or combinations of gases.

Contemplated high efficiency heat management devices for use with a component comprise at least one jet inlet, wherein the at least one jet inlet comprises a suitable shape. In some embodiments, the shape is square or rectangular. Other shapes are also contemplated. In some embodiments, a contemplated high efficiency heat management device comprises at least one jet inlet that has a two-dimensional configuration or a three-dimensional configuration.

Contemplated jet inlets comprise or have a vertical enclosure having a top, a bottom, and at least one side. These designs are shown in Table 1. As shown, contemplated at least one jet inlet comprises or has a tapered directional component coupled with the bottom of the vertical enclosure.

Contemplated high efficiency heat management devices for use with a component comprise at least one component having a high heat flux value, wherein the component has a top surface. Contemplated high efficiency heat management device for use with a component comprises a channel base of the at least one porous filled channel configuration component or at least one foam filled channel configuration component that is operationally near, coupled with, or connected to the top surface of the component. Contemplated devices have several applications, including but not limited to, components such as electronics, biomedical devices, and powered electrical equipment, such as x-rays, lasers, ultrasound equipment, radiography machines, surgical equipment, and solar radiation receivers.

### EXAMPLES

### Example 1: Two-Dimensional and Three-Dimensional Configurations

Conductive porous filled heat exchangers with single or multiple jet impingements are numerically investigated employing local thermal non-equilibrium model in porous media (FIG. 1). The heat exchangers consist of confined, narrowing, porous filled channels or foam filled channels subject to uniform heat flux leaving the devices to be cooled. The inflow coolant enters through vertical inlet channels, passes through the porous material along inclined channels and leaves through the two lateral, open-volume exit channels. In all studied cases, the maximum thickness of the porous substrate, located under the central jet inlet, is 0.13 of the length of the porous insert at the base (L=5.25 cm). The thickness reduces to 0.048 L at the exit channels. The porous substrate is constructed from copper and has a porosity value of 0.45 with a filament thickness of 4.315×10⁻⁴ m [14]. The base surface of the heat exchanger is exposed to a uniform heat flux of 10⁵ W/m² and all other walls are assumed to be insulated. Fluid enters the heat exchangers at 300K with a uniform velocity, and flow would be hydraulically developed before reaching the porous insert.

In this work, single and multi-jet inlets are investigated. The shape of the inlet cross section is either square or rectangular (elongated along the transverse direction), for both single and multi-jet injections. The heat exchangers with square jet inlets have porous inserts that taper off the same in all four directions from maximum substrate thickness at each edge of the main central inlet to the minimum substrate thickness at the base's edges (FIG. 1d). The inlet channel thickness in the single inlet heat exchangers (tᵢ) is 0.33 L. In multi jet cases, certain geometrical parameters are investigated such as location, orientation and size of jet inlet channels.

Several two-dimensional multi-inlet porous filled heat exchangers are numerically modeled to obtain an advantageous design for the size and location of multi jet inlets along streamwise direction (Table 1). The studied cases are categorized in three sets; the first set with the thickest inlet at the center and two narrow symmetric peripheral lateral jets, the second set with similar inlet sizes, and the third set with the narrowest inlet at the center and two thick symmetric peripheral lateral jets. The thicknesses of central and peripheral inlets are indicated in Table 1 for each set. For each set, the effect of distance between the central and peripheral inlet channels (Iₓ) is also examined by studying multiple cases for each set (Table 1). In addition, for studying the effect of inclined channel walls on base wall temperature value and uniformity, cases H2d and I2d are studied. These cases are equivalent to case B2d but with parallel channels with thickness of 0.048 L and 0.13 L, respectively, which are the minimum and maximum channel thicknesses of case B2d. For all two-dimensional studies, flow enters with a velocity of 3 cm/s and temperature of 300 K.

For three dimensional designs, single inlet Cases A3d and B3d are developed based on the two-dimensional case A2d with rectangular and square cross sections respectively, and so with the inlet thickness of tᵢ=0.33 L (Table 2). To design three dimensional multi jet inlet cases, the obtained advantageous design from two-dimensional study (case B2d) is utilized indicating the size and location of inlet jets along streamwise direction. For the multi inlet geometries (Table 2), the peripheral inlets are parallel to the central inlet and located along the narrowing channels. The central inlet channel in these cases has a thickness of 0.66 tᵢ (i.e. t_{ic}=0.218 L) and the thickness of peripheral channels are each 0.17 tᵢ (i.e. tᵢₚ=0.056 L). However, for all studied three-dimensional cases (with single or multiple inlets), flow enters with similar overall flow rate of 27.29 cm³/sand temperature of 300 K. As such, the inflow velocity is adjusted for each design to provide similar volume flow rate. For single inlet channel cases of A3d and B3d, inflow velocity values are 3 cm/s and 9.091 cm/s, respectively. For each multi inlet case, inflow velocity values are identical in all central and peripheral inlets. The inflow velocity is 3 cm/s for case C3d, while the velocity for the cases with multi square cross section inlets (Table 2, cases D3d-O3d) are 18.425 cm/s, 16.493 cm/s, 14.928 cm/s, 13.634 cm/s, 11.619 cm/s, and 10.82 cm/s for cases with 2, 4, 6, 8, 12, and 14 peripheral inlets, respectively.

Two coolants of water and 5% titanium dioxide (TiO₂) in water nanofluid are investigated. The coolants are treated as homogenous liquids with Newtonian behavior whose effective properties are presented in Table 3 [15, 30, 34-36]. Some of the represented data and discussions will focus on the streamwise and transverse centerlines of the three-dimensional geometries. The streamwise centerline is the center base line towards the exit channels (along x axis), and the transverse centerline is the center base line perpendicular to streamwise line (along z axis).

### GOVERNING EQUATIONS

Two different regions will be analyzed in this system; the porous substrate and the entrance/exit channels.

Inlet-Exit Channels:

The governing equations used for steady state, incompressible, single phase, and laminar flow inside the entrance and exit channels are:

V̅·\vec{v}=0 (1)

ρ_{ƒ}\vec{v}·V̅\vec{v}=−V̅P+μV²\vec{v} (2)

ρ_{ƒ}c_{ƒ}(\vec{v}·V̅T)=k_{ƒ}V²T (3)

They represent the continuity, momentum, and energy equations, respectively.

Porous Substrate:

For the porous region of the system, the steady state, single phase, and volume averaged governing equations are [14]:

$$\begin{matrix}∇ \cdot 〈 {v}^{} 〉 = 0 & ( 4 ) \\ \frac{ρ f}{ɛ} 〈 ( {v}^{} \cdot ∇ ) {v}^{} 〉 = - ∇ {〈 P 〉}^{f} + \frac{μ}{ɛ} {∇}^{2} 〈 {v}^{} 〉 - \frac{μ}{K} 〈 {v}^{} 〉 - \frac{{ρ}_{f} F ɛ}{\sqrt{K}} [ 〈 {v}^{} 〉 \cdot 〈 {v}^{} 〉 ] J & ( 5 ) \\ {k}_{f , eff} {∇}^{2} {〈 {T}_{f} 〉}^{f} + {h}_{i} {a}_{i} ( {〈 {T}_{s} 〉}^{s} - {〈 {T}_{f} 〉}^{f} ) = {ɛρ}_{f} {c}_{f} 〈 {v}^{} 〉 \cdot ∇ {〈 {T}_{f} 〉}^{f} & ( 6 ) \\ {k}_{s , eff} {∇}^{2} {〈 {T}_{s} 〉}^{s} - {h}_{i} {a}_{i} ( {〈 {T}_{s} 〉}^{s} - {〈 {T}_{f} 〉}^{f} ) = 0 & ( 7 ) \\ \text{where:} & \\ F = \frac{β}{\sqrt{{αɛ}^{3}}} & ( 8 ) \\ K = \frac{{ɛ}^{3} {d}_{f}^{2}}{{α ( 1 - ɛ )}^{2}} & ( 9 ) \\ {k}_{f , eff} = ɛ {k}_{f} & ( 10 ) \\ {k}_{s , eff} = ( 1 - ɛ ) {k}_{s} & ( 11 )\end{matrix}$$

where β and α are equal to 1.75 and 150, respectively [5]. The interstitial heat convection coefficient (hᵢ) and interfacial surface area (aᵢ) are evaluated from the following equations [37]:

$$\begin{matrix}\frac{{h}_{i} df}{{k}_{f}} = 0.52 {( \frac{{ud}_{f}}{ɛ υ} )}^{0.5} {Pr}^{0.37} & ( 12 ) \\ {a}_{i} = \frac{3 π {d}_{f}}{{( 0.59 {d}_{p} )}^{2}} [ 1 - {e}^{- ( ( 1 - ɛ ) / 0.04 )} ] & ( 13 )\end{matrix}$$

where u represents the average fluid velocity in the porous substrate region. The pore diameter (dₚ) is obtained from the following equations [38]:

$$\frac{{d}_{f}}{{d}_{p}} = 1.18 \sqrt{\frac{( 1 - ɛ )}{3 π}} \frac{1}{1 - {e}^{- ( ( 1 - ɛ ) / 0.04 )}} \qquad ( 14 )$$

Note that the pore diameter (dₚ) could be representing cell diameter in [37-38]. Cell diameter is the diameter of the average polyhedron of the metal foam, while pore diameter is the diameter of the average face of the polyhedron.

### Numerical Methodology

For numerical modeling, an implicit, pressure-based, cell-centered control volume method is employed to solve the coupled and non-linear governing equations [15]. Utilizing ANSYS FLUENT, the governing equations are first discretized to convert the nonlinear equations to linear forms. The gradients are evaluated utilizing the Least Squares Cell Based method. Convective terms are discretized using a second order upwind scheme, while a central differencing scheme is utilized for diffusive terms and cell face pressure. The SIMPLE pressure-based segregated algorithm is utilized and would iterate until the scalar's globally scaled residual reaches a minimum of 10⁻⁶, as convergence criteria. Iterative method of Gauss-Seidel along with Algebraic Multigrid (AMG) scheme is utilized [15].

Two equation energy model in porous media is employed in this study utilizing the assumption of local thermal non-equilibrium between solid and fluid phases. As such, two coincident grids are generated for porous filled region, one for the porous matrix solid phase and one for the fluid phase. Energy transfer between the phases is dictated by interstitial heat convective coefficient (hᵢ) and interfacial surface area (aᵢ). The fluid and solid phases are connected to the heat exchanger base wall that is subject to a uniform high heat flux. The coupled interface between the phases and the base would allow energy to freely flow between the base and the phases. Inflow and outflow boundary conditions are applied at the inlet and outlet boundaries, all other surfaces are adiabatic walls with no slip condition, except base surface, which is subjected to a uniform heat flux. To represent results, non-dimensional base temperature (⊖_{w}) is defined as:

$$\begin{matrix}{θ}_{w} = \frac{{k}_{s} ( \text{?} - \text{?} )}{\text{?}} & ( 15 ) \\ \text{?} \text{indicates text missing or illegible when filed} & \end{matrix}$$

### Grid Independence Study

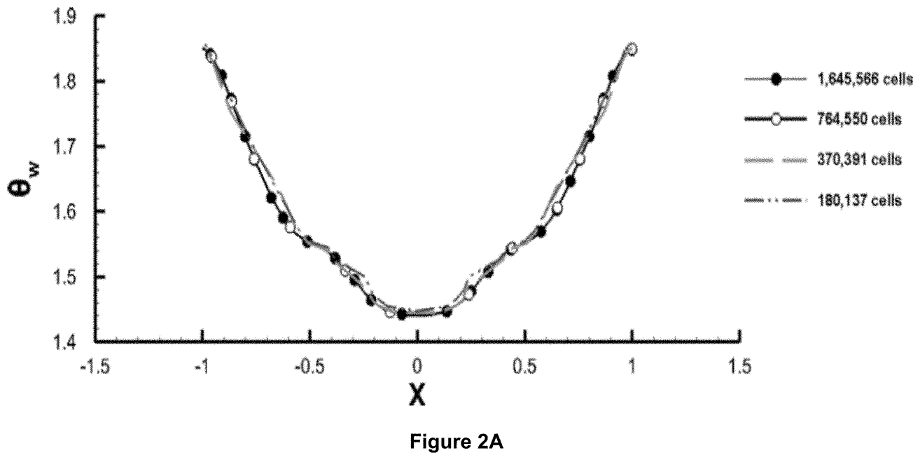

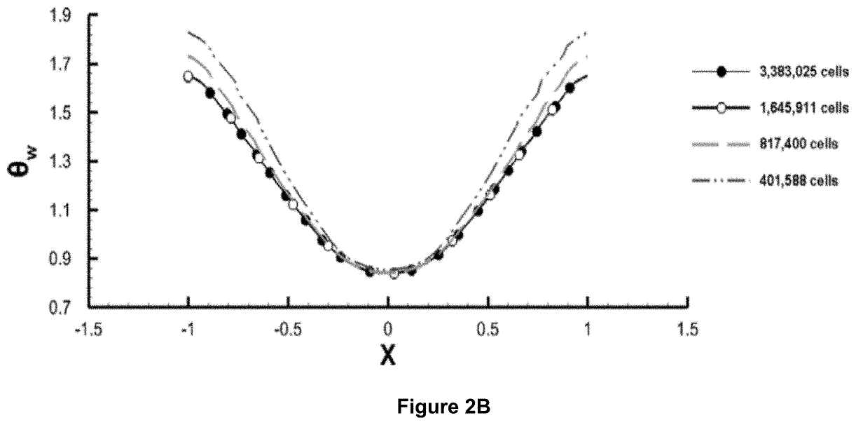

For grid generation, a quadrilateral structured multi-block mesh is utilized. In order to properly capture flow field characteristics, finer mesh sizes are applied within the porous region and adjacent to the wall boundaries. For each investigated studied case, grid independence study is performed by studying multiple grid sizes to make sure the results are independent of grid sizes. For instance, in FIG. 2, non-dimensional temperature distributions along the streamwise centerline for different grid sizes are compared for cases of C3d and N3d (defined in Table 1). All studied cases consist of a copper porous substrate with the porosity of 0.45 and are subject to a uniform heat flux of 10⁵ W/m². The working fluid is set to be water and the two-equation model with the assumption of local thermal non-equilibrium is employed for modeling thermal transport through porous media. The results indicate that the grids with 764,550 cells and 1,645,911 cells result in a grid independent solution for the cases of C3d and N3d, respectively (FIG. 2).

### Code Validation Study

To validate numerical modeling and results, a uniform cross section porous filled channel subject to a constant heat flux at its one side is numerically simulated (FIG. 3a). The other side of the channel is insulated. The analytical solution for flow through this channel is presented in [39]. The non-dimensional temperature profiles for solid and fluid phases obtained from the present numerical study are validated against those of the analytical solution [39] for two different values of non-dimensional heat generation (Φ) within the porous solid matrix (FIG. 3). The Biot number (Bi), porosity (ε) and the ratio of the effective thermal conductivity of fluid to that of solid (κ), defined in the following equations [39], are selected to be 10, 0.1, and 0.11, respectively. The investigated non-dimensional heat generation values are 0 and 1 [39].

$$\begin{matrix}Bi = \frac{{h}_{i} {a}_{i} {H}^{2}}{{k}_{s , eff}} & ( 16 ) \\ κ = \frac{{k}_{f , eff}}{{k}_{s , eff}} & ( 17 ) \\ Φ = \frac{( 1 - ɛ ) H {\dot{q}}_{gen}}{{q}_{w}} & ( 18 )\end{matrix}$$

where, H is the channel height. The comparison of the numerical and analytical temperature profiles for both fluid and solid phases indicates an excellent agreement in the results for different non-dimensional heat generation values (FIG. 3).

### Results

Multi jet impingements through high conductive porous filled heat exchangers are developed based on earlier studies on single jet impingement [29]. Local thermal non-equilibrium model in porous media is employed to accurately capture solid and fluid phase temperatures. The temperature values for single and several multi jet impingement cases are compared and analyzed for different jet shape, location and orientation to obtain proper designs with low and uniform temperature values at the base wall subject to a high heat flux.

### Size and Location of the Inlet Channels in Multi Jet Impingement

The size and location of multi jet inlets along streamwise direction is investigated by studying multiple cases categorized as three geometrical sets (Table 1). Comparing the results of three sets indicate that the cases with thicker cross-sectional central jet (set 1) provide lower and more uniform temperature values on the base wall and so more efficient cooling (FIG. 4). Note that the overall inflow volume flow rate and velocity are kept the same for all these studied cases. As such, a reduction in the thickness of the central jet inlet results in a larger thickness for the lateral peripheral jets and larger flow rate passing through peripheral jets. Therefore, lower flow rate would pass through the central jet resulting in less interaction between the coolant and conductive solid porous structure and less thermal transport and cooling effectiveness. That confirms the advantage of set 1 compared to the other sets.

In addition, multiple designs are investigated for each set to evaluate the effects of location of the jet inlets on the base temperature distribution (Table 1). The distance between the centers of central and peripheral jets is indicated as Iₓ. Comparing the base temperature distribution for all sets depicts that the further the peripheral jet inlets move away from the central jet, the higher and more non-uniform the surface temperatures are likely to be (FIG. 4). This is mostly due to the fact that the coolant injected from the peripheral jets would leave from the closest exits and so have less engagement with porous substrate during the cooling process when peripheral jet inlets get closer to the exits.

The studied multi jet inlet cases are also compared with single jet inlet case (Case A2d). In the single jet case, the stagnation region in front of the jet causes a sinusoidal like behavior temperature profile with a high temperature peak and low cooling effectiveness at the center of the base [29]. This issue can be resolved by proper design of multi jet impingement heat exchanger. For instance, case B2d can resolve this issue while providing low temperature and appropriate temperature uniformity on the base (FIG. 4). Having further or larger peripheral jets would also resolve the high temperature peak issue at the stagnation point in front of the jet impingement but results in higher temperature values and larger temperature non-uniformity (FIG. 4).

### Porous Filled Channel Thickness and Inclined Walls

The heat exchangers in this work employ inclined walls to better control the base temperature uniformity. It is shown that for the cases with single jet inlet, the selected inclination angle can better provide low and uniform temperature at the base compared to the cases without an inclination angle [29]. The effect of the inclined wall for multi jet impingement is investigated in FIG. 5 by comparing the advantageous design obtained earlier (caseB2d) with two parallel channels whose thicknesses are the same as the minimum and maximum thickness of case B2d, defined as cases F2d and G2d in Table 1. The non-dimensional temperature distribution indicates that caseB2d provides a more uniform temperature profile at the base. The thin parallel channel may provide less temperature values, but it provides a considerably non-uniform and sinusoidal like behavior temperature profile with a high temperature peak at the base center (FIG. 5).

### Orientation and Placement of the Inlet Channels in Multi Jet Impingement

For evaluation of shape, location, and orientation of jets in multi jet injection, multiple designs are studied which are developed based on the advantageous case B2d (Table 2). Case C3d has rectangular multi inlets elongated in transverse direction and cases D3d-O3d employ square cross section multi inlets. In FIG. 6, non-dimensional temperature distributions along streamwise and transverse centerlines are compared for all these studied cases. The coolant is water and the base of each heat exchanger is subject to the heat flux of 10⁵ W/m². The results indicate that the cases with rectangular cross-section elongated in transverse direction (cases A3d and C3d) result in a more uniform temperature profile. However, the base wall temperature values are generally higher compared to those of the cases with square cross-sectional inlets, especially along streamwise direction (FIG. 6a). Comparing square cross sectional multi jet cases, cases with proper peripheral jets in transverse direction (G3d, H3d, L3d, M3d, N3d, O3d) can better provide temperature uniformity along transverse direction as well as having low temperature values. Note the entering flow rate is the same in all cases and the velocity is adjusted based on the cross-section surface area.

Non-dimensional temperature contours at the base wall are presented for all studied cases (A3d-O3d) in FIG. 7. As expected, the contours depict an almost uniform temperature distribution along streamwise direction with no change in transverse direction for the cases of A3d and C3d with rectangular cross sections. The single inlet case B3d does not provide proper cooling along the walled edges (Z=−1 and Z=1). Among the cases with multi square cross-sectional inlets, higher temperature values are seen at the ends of the transverse direction in the cases with the closest peripheral jets to the central jet (cases D3d, E3d, I3d), indicating low heat transfer effectiveness in these designs (FIG. 7). In general, the flow moves towards the exits and avoid flowing in the transverse direction towards the walled edges. By moving the peripheral inlets closer to these walls, the low heat transfer band is minimized (Cases F3d and K3d, FIG. 7). When the peripheral jet inlets reach the edges, the low heat transfer band starts to break apart (Cases G3d, J3d, L3d, N3d, FIG. 7). In addition, adding peripheral jets near the central jet along streamwise direction can result in lower temperature values along streamwise direction (cases H3d, M3d, O3d, FIG. 7). In overall, cases G3d and H3d result in larger area with very low temperature values in the central region of the base, compared to the other cases. However, the cooling of the base corners is not as well as the other regions. Case O3d provides the most uniform temperature distribution over the base, in comparison with other cases with square inlets, especially in the central region. Case O3d results in a considerably smaller area of very low temperature at the base compared to cases G3d and H3d (FIG. 7).

Solid and Fluid Phase Temperature Profiles within Porous Substrate

In this work, two equation energy model in porous media is employed considering local thermal non-equilibrium between fluid and solid phases. The obtained non-dimensional solid and fluid temperature profiles along the vertical coordinate are investigated for single and multi-inlet cases of A3d and C3d, for porosity values of 0.45 and 0.9. The profiles are presented for different locations within the porous substrate; at the center (X=0), at the porous exit (X=1), and in the middle of them (X=0.5) as depicted in FIG. 8. In all temperature profiles, the maximum temperature occurs at the base wall (Y=0) which is subject to a uniform high heat flux value. Both solid and fluid temperatures decrease while getting far from the base. In addition, the results show that increasing the porosity value results in more deviation between solid and fluid temperature profiles. This is due to the fact that porosity is inversely proportional to the volumetric heat transfer coefficient [40], i.e. high porosity corresponds to low volumetric heat transfer coefficient and so more temperature difference between solid and fluid phases. That indicates the importance of employing the two-equation model for studying thermal transport through porous substrate especially for high porosity values. At each point, the difference between the fluid and solid phase temperatures also changes by location and the largest deviation is observed near the exit of porous substrate (X=1). At high porosity values, the fluid temperature profile does not change considerably as flow moves through the substrate while the solid temperature values change. Comparing single and multi-inlet cases (A3d and C3d), non-dimensional fluid and solid temperature profiles show somehow similar behavior and a little difference is observed between the temperature values of these cases.

### Effect of TiO₂ Nanofluid Coolant and Porosity

The effect of utilization of 5% titanium dioxide (TiO₂) in water nanofluid coolant is investigated for porosity values of 0.45 and 0.90 in FIG. 9. The comparison of non-dimensional temperature profiles of cases A3d and C3d at the base along streamwise direction are compared for water and TiO2 nanofluids coolants for porosities of 0.45 and 0.9 in FIGS. 9 a,b. The results show that utilization of TiO₂ nanofluid reduces the base temperature and therefore improves cooling effectiveness regardless of the porosity value and geometry. Similar to the results for water coolant, the results indicate more temperature uniformity along the base of the multi inlet case in comparison with the single inlet case (FIG. 9a, b). A reduction in porosity results in lower base temperature but larger pressure drop. The multi inlet channel design is developed to eliminate high temperature peak at the stagnation point and to provide more temperature uniformity along the base.

Non-dimensional temperature profiles of the single inlet case B3d and six different multi inlet channel cases (D3d, G3d, H3d, L3d, M3d, N3d, and O3d) at the base along streamwise direction are studied employing 5% titanium dioxide (TiO₂) in water nanofluid coolant for porosity of 0.45 (FIG. 9c). Comparing the results presented in FIGS. 6a and 9c indicate the improvement of cooling either by utilization of TiO₂ nanofluid or by using cases G3d and H3d.

### Example 2: Analysis of Contemplated Porous Filled Heat Exchangers

### Code Validation Study

To validate the numerical modeling and the results, the velocity and temperature profiles are validated against those of analytical solution by Vafai and Kim [16], for a fully developed flow through a porous filled parallel-plate channel, subject to a uniform heat flux from both plates. The comparisons are performed for two different values of inertia parameters (K) at a Darcy number of Da^{-1/2}=10, defined as [16]

$$\begin{matrix}\text{?} = \frac{1}{{H}^{2}} \frac{K}{\text{?}} & ( 10 ) \\ A = \text{?} \text{?} \frac{\text{?}}{\text{?}} & ( 11 ) \\ \text{?} \text{indicates text missing or illegible when filed} & \end{matrix}$$

where 2H indicates the channel height. The comparison of the results indicates an excellent agreement for velocity and temperature profiles for different inertia parameters (FIG. 10).

### Grid Resolution Study

A multi-block structured quadrilateral grid is utilized for grid generation while mesh sizes are set to be finer within the porous region and near the wall boundaries to properly capture flow field characteristics. In order to study grid independence of the results, several grid sizes are examined. As an example, the non-dimensional temperature distributions along the streamwise centerline of the investigated heat exchanger, with rectangular and square cross sectional inlets and a porosity of 0.45, are presented for different grid sizes in FIG. 11. It can be seen that a gird resolution composed of 613,000 cells (for rectangular cross section) and 1,032,000 cells (for square cross section) result in a grid independent solution while properly capturing the flow field characteristics. Varying the imposed heat flux led to the same conclusion regarding the adequate number of cells for a grid independent solution.

### Results

Porous filled heat exchanges with rectangular and square cross section inlet channels are investigated. The effect of inclination angle, heat flux, coolant velocity, porous material, porosity value and multiple nanofluid coolants are studied. The heat exchanger design utilizes inclined walls to improve temperature uniformity along the base subject to a high heat flux value. The importance of the channel inclined walls is investigated in FIG. 12. The streamwise non-dimensional temperature at the centerline of the base surface of four different copper porous filled heat exchanger designs are compared. The porosity of the copper is 0.45 and all designs are subject to a uniform heat flux of 10⁶ W/m² and employ rectangular cross section inlet. Two designs employ inclined walls; one with an inclination angle of 5.96° and the other one with an angle of 13.74°. As such, the thickness of the porous filled channels varies between 0.13 L and 0.095 L for the inclination angle of 5.96° and between 0.13 L and 0.048 L for the inclination angle of 13.74°. The other two designs employ parallel channels; i.e. zero inclination angle, whose thicknesses are the same as the maximum and minimum thickness of the investigated counterpart cases with inclined walls (0.13 L and 0.048 L). As the results indicate, the cases with inclined walls provide a considerably more uniform temperature distribution. Decreasing the channel thickness, without utilizing the inclined walls, may result in lower temperature at some locations but larger temperature non-uniformity would be obtained (FIG. 12). As such, a heat exchanger with an inclination angle of 13.74° is selected in this study providing low temperature values and most temperature uniformity along the base centerline. In many cooling applications, the goal is to provide a uniform temperature at the surface while keeping the surface at low temperature.

The effect of inlet velocity value on the temperature distribution on the base is also investigated for a copper foam filled heat exchanger with rectangular cross sectional inlet and porosity of 0.45 which is subject to a uniform heat flux of 10⁶ W/m² for the same coolant temperature of 300 K (FIG. 13). An increase in the velocity, and so mass flow rate, will result in lower and more uniform temperature distribution on the base. However, a higher velocity value will cause a larger pressure drop and so higher required pumping power. To investigate the effect of heat flux in this study, different heat flux values are investigated for a copper foam filled heat exchanger with a porosity of 0.45. The coolant temperature and velocity are set to be 300 K and 4 cm/s, respectively. To better study the temperature distribution on the base, the temperature values are once non-dimensionalized using a fixed value of heat flux (10⁶ W/m²) (FIG. 14a) and once non-dimensionalized using the corresponding heat flux (FIG. 14b). As expected, higher heat flux corresponds to a higher surface temperature (FIG. 14a). However, as FIG. 14b indicates, the non-dimensional temperature distribution and uniformity are independent of heat flux value when temperature is non-dimensionalized using the corresponding heat flux value. As such, regardless of the heat flux value, the temperature profiles are similar.

The effects of porous materials, namely copper and APG, and porosity value are studied for rectangular and square cross-sectional inlet channels (FIG. 15). The results indicate that both copper and APG can properly cool down the base which is subjected to a very high heat flux value. Our investigations confirm the importance of employing the porous substrate in the heat exchanger design to decrease the base temperature below a safe temperature value. Comparing the investigated porous substrates, APG porous substrate can provide a better cooling over the base, for all studied coolants of pure water and water based nanofluids, and for high and low porosity values. APG is a lighter and more conductive material, but fragile in comparison with copper. In addition, as expected, a reduction in porosity improves cooling effectiveness for all studied cases (FIG. 15). As such, the maximum temperature can be reduced by either utilization of a more conductive material or by a reduction in porosity. However, a lower porosity value results in a larger pressure drop and so higher required pumping power.

The effect of different nanofluid coolants are also investigated in FIG. 15a-c. The studied nanofluid coolants are 5% titanium dioxide (TiO₂) in water, 1% alumina in water, 0.03% multi walled carbon nanotubes (MWCNT) in water, and 1% diamond in 40:60 ethylene glycol/water. The results indicate that titanium dioxide (TiO₂) nanofluid coolant has more cooling effectiveness compared to other studied coolants (nanofluids and water), for both copper and APG porous matrices for high and low porosity values. Comparing the studied coolants, diamond nanofluid has the lowest thermal effectiveness in comparison with pure water and all other studied water based nanofluid coolants.

Investigation of temperature distribution over the base indicates a sinusoidal like behavior with a high temperature peak at the center point of the base, for all the studied cases (FIG. 15a-c). The center peak is due to development of stagnation point at the center of the base and the fluid's deceleration as it moves towards that region. On both sides of the stagnation point, more efficient cooling is achieved as such minimum temperature regions are developed. As expected, the highest temperature values are observed near the exit channels for all cases.

The effect of the inlet cross section on temperature distribution is also presented in FIG. 15a-c. To better investigate the effect of inlet cross section, the mass flow rate is kept the same at the entrance of both rectangular and square inlets. As such, the entrance velocity for the cases with rectangular cross section is set to be 4 cm/s while it is 12.12 cm/s for the cases with square cross section. The results indicate lower temperature values and therefore an improved cooling effectiveness along the streamwise direction, for all cases with square cross sections compared to those with rectangular cross section. In square cross-sectional inlet channel, titanium dioxide (TiO₂) nanofluid coolant provides more cooling effectiveness compared to other studied coolants (nanofluids and water), for both copper and APG porous matrices for different porosity values. In summary, similar results are observed regarding the effect of porous material, porosity and nanofluids for both square and rectangular cross section channels.

Temperature distribution along the transverse direction at the centerline of the base is also studied and compared for different coolants, porous materials, and porosity values (FIG. 16 a-c). The results confirm that titanium dioxide (TiO₂) nanofluid coolant has more cooling effectiveness compared to other studied coolants (nanofluids and water), for both copper and APG porous matrices for high and low porosity values. In addition, the diamond nanofluid has the lowest thermal effectiveness compared to pure water and all other studied water based nanofluid coolants. Also similar to the results for the rectangular cross-sectional inlet cases, APG porous substrates provides a better cooling along the transverse direction compared to that of copper substrate for the same coolant or porosity. In addition, the lower porosity would result in more efficient cooling along the transverse direction but at a greater pressure drop. Studying the effect of inlet cross section, the results indicate larger temperature non-uniformity along the transverse direction for the cases with a square cross section. In addition, larger temperature values are observed in the regions far from the inlet channel (FIG. 16a-c). As such, the cases with square cross section provide lower temperature values along the streamwise direction while result in less uniformity specially along transverse direction. Utilization of APG or low porosity substrates improves cooling effectiveness along the transverse direction.

Electronic cooling is one of the main issues in the development of advanced devices such as electronics and biomedical components. In this work, an innovative porous filled heat exchanger is numerically modeled to investigate the thermal performance of different nanofluid coolants, porous materials, porosity values, and inlet channel geometry. The heat exchanger is filled with a highly conductive porous insert providing a large surface area for a given volume to enhance heat transfer and thermal control. Two different porous solid materials (copper and annealed pyrolytic graphite (APG)) with different porosity values, utilizing different nanofluids (5% titanium dioxide (TiO₂) in water, 1% alumina in water, 0.03% multi walled carbon nanotubes (MWCNT) in water, and 1% diamond in 40:60 ethylene glycol/water) are investigated. The results indicate the importance of proper selection of the porous medium and the coolant for improving the cooling process. Both copper and APG porous substrates can provide a proper cool-ing at the base of the heat exchanger with rectangular and square inlet channels. However, utilization of APG porous matrix provides a better cooling at the base leading to lower temperature values. APG is a lighter and more conductive material, but fragile in comparison with copper. The results also show that utilizing titanium dioxide (TiO₂) nanofluid as coolant improves cooling efficiency in all cases with rectangular and square cross-sectional inlets, copper and APG porous matrices, and low and high porosity values. The effect of inlet channel geometry, square and rectangular, was also investigated. The results indicate a lower temperature distribution along streamwise direction for the cases with square cross-sectional inlet, while along the transverse direction higher temperature values are observed far from the center for the square cross section inlet channel.

Thus, specific embodiments, methods of use of high efficiency thermal management devices for use with components having high heat or temperature flux values have been disclosed. It should be apparent, however, to those skilled in the art that many more modifications besides those already described are possible without departing from the inventive concepts herein. The inventive subject matter, therefore, is not to be restricted except in the spirit of the disclosure herein. Moreover, in interpreting the specification and claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

### REFERENCES

[1] Y. A. Cengeland A. J. Ghajar, Heat and Mass Transfer: Fundamentals & Applications, McGraw-Hill, New York, 2015.
[2] S. Mahjoob and K. Vafai, “A Synthesis of Fluid and Thermal Transport Models for Metal Foam Heat Exchangers,” International Journal of Heat and Mass Transfer, vol. 51, no. 15, pp. 3701-3711, 2008.
[3] J. S. Bintoro, A. Akbarzadeh, and M. Mochizuki, “A Closed-Loop Electronics Cooling by Implementing Single Phase Impinging Jet and Mini Channels Heat Exchanger,” Applied Thermal Engineering, vol. 25, no. 17, pp. 2740-2753, 2005.
[4] M. Iyengar and M. Jr. Ellsworth, “Design and Analysis of Direct Liquid Multi-Jet Impingement Schemes for Electronics Applications,” ASME International Mechanical Engineering Congress and Exposition, vol. 2, pp. 249-256, 2004.
[5] K. Vafai, Handbook of Porous Media, 3^{rd} Edition, CRC Press, Taylor & Francis, Boca Raton, F L, 2015
[6] A. Sivasamy, V. Selladurai, and P. R. Kanna, “Jet Impingement Cooling of a Constant Heat Flux Horizontal Surface in a Confined Porous Medium: Mixed Convection Regime,” International Journal of Heat and Mass Transfer, vol. 53, no. 25, pp. 5847-5855, 2010.
[7] N. H. Saeid and A. A. Mohamad, “Jet Impingement Cooling of a Horizontal Surface in a Confined Porous Medium: Mixed Convection Regime,” International Journal of Heat and Mass Transfer, vol. 49, no. 21, pp. 3906-3913, 2006.
[8] K. C. Wong and N. H. Saeid, “Numerical Study of Mixed Convection on Jet Impingement Cooling in an Open Cavity Filled with Porous Medium,” International Communications in Heat and Mass Transfer, vol. 36, no. 2, pp. 155-160, 2009.
[9] A. P. Rallabandi, D. H. Rhee, A. Gao, and J. C. Han, “Heat Transfer Enhancement in Rectangular Channels with Axial Ribs or Porous Foam under Through Flow and Impinging Jet Conditions,” International Journal of Heat and Mass Transfer, vol. 53, no. 21, pp. 4663-4671, 2010.
[10] P. Wang, K. Vafai, and D. Y. Liu, “Analysis of Radiative Effect Under Local Thermal Non-Equilibrium Conditions in Porous Media-Application to a Solar Air Receiver,” Numerical Heat Transfer, Part A: Applications, vol. 65, no. 10, pp. 931-948, 2014.
[11] E. M. G. Rodrigues, R. Melicio, V. M. F. Mendes, and J. P. S. Catalao, “Simulation of a Solar Cell considering Single-Diode Equivalent Circuit Model,” Renewal Energy and Power Quality Journal, vol. 1, pp. 369-373, 2011.
[12] C. Zing and S. Mahjoob, “Numerical Analysis of Thermal Transport in Nano Fluidic Porous Filled Heat Exchangers for Electronics Cooling,” ASME Summer Heat Transfer Conference, vol. 1, 2017.
[13] L. Tadrist, M. Miscevic, O. Rahli, and F. Topin, “About the use of Fibrous Materials in Compact Heat Exchangers,” Experimental Thermal and Fluid Science, vol. 28, no. 2, pp. 193-199, 2004.
[14] S. Mahjoob, K. Vafai, and N. R. Beer, “Rapid Microfluidic Thermal Cycler for Polymerase Chain Reaction Nucleic Acid Amplification,” International Journal of Heat and Mass Transfer, vol. 51, no. 9, pp. 2109-2122, 2008.
[15] Fluent 17.1.0, User Guide, 2016.
[16] K. Vafai and S. Kim, “Forced Convection in a Channel Filled with Porous Medium—An Exact Solution,” ASME J. Heat Transfer, vol. 111, pp. 103-110, 1989.
[17] Bhattacharya, A., and Mahajan, R. L. “Metal Foam and Finned Metal Foam Heat Sinks for Electronics Cooling in Buoyancy-Induced Convection.” Journal of Electronic Packaging Vol. 128 No. 3 (2006): pp. 259-266.
[18] Feng, S. S., Kuang, J. J., Wen, T., Lu, T. J., and Ichimiya, K. “An Experimental and Numerical Study of Finned Metal Foam Heat Sinks under Impinging Air Jet Cooling.” International Journal of Heat and Mass Transfer Vol. 77 (2014): pp. 1063-074.
[19] Feng, S. S., Kuang, J. J., Wen, T., Lu, T. J., and Ichimiya, K. “An Experimental and Numerical Study of Finned Metal Foam Heat Sinks under Impinging Air Jet Cooling.” International Journal of Heat and Mass Transfer Vol. 77 (2014): pp. 1063-074.
[20] Shih, W. H., Chou, F. C., and Hsieh, W. H. “Experimental Investigation of the Heat Transfer Characteristics of Aluminum-foam Heat Sinks with Restricted Flow Outlet.” Journal of Heat Transfer Vol. 129 No. 11 (2007): pp. 1554-1563.
[21] Bhattacharya, Anandaroop, Calmidi, Varaprasad V., and Mahajan, Roop L.—Thermophysical Properties of High Porosity Metal Foams. International Journal of Heat and Mass Transfer Vol. 45 No. 5 (2002): pp. 1017-1031.
[22] Iasiello, Marcello, Bianco, Nicola, Chiu, Wilson K. S., and Naso, Vincenzo.—Thermal Conduction in Open-Cell Metal Foams: Anisotropy and Representative Volume Element. International Journal of Thermal Sciences Vol. 137 (2019): pp. 399-409.
[23] Ranut, Paola. “On the Effective Thermal Conductivity of Aluminum Metal Foams: Review and Improvement of the Available Empirical and Analytical Models.” Applied Thermal Engineering Vol. 101 (2016): pp. 496-524.
[24] Hwang, Jenn J., Hwang, G. J., Yeh, Rong H., and Chao, Chung H. “Measurement of Interstitial Convective Heat Transfer and Frictional Drag for Flow across Metal Foams.” Journal of Heat Transfer Vol. 124 No. 1 (2002): pp. 120-129.
[25] Zhao, Chang Y., Lu, Wei, and Tassou, Savvas A. “Thermal Analysis on Metal-Foam Filled Heat Exchangers. Part II: Tube Heat Exchangers.” International Journal of Heat and Mass Transfer Vol. 49 No. 15 (2006): pp. 2762-2770.
[26] Rachedi, R. and Chikh, Salah. “Enhancement of Electronic Cooling by Insertion of Foam Materials.” Heat and Mass Transfer Vol. 37 No. 4 (2001): pp. 371-378.
[27] Boomsma, Kevin, Poulikakos, Dimos, and Zwick, F. “Metal Foams as Compact High Performance Heat Exchangers.” Mechanics of Materials Vol. 35 No. 12 (2003): pp. 1161-1176.
[28] Das, Sarit K., Choi, Stephen U. S., and Patel, Hrishikensh E. “Heat Transfer in Nanofluids—a Review.” Heat Transfer Engineering Vol. 27 No. 10 (2006): pp. 3-19.
[29] Zing, Carlos, Mahjoob, Shadi, and Vafai, Kambiz. Analysis of Porous Filled Heat Exchangers for Electronic Cooling. International Journal of Heat and Mass Transfer Vol. 133 (2019): pp. 268-276.
[30] Khanafer, Khaliland Vafai, Kambiz. “A Critical Synthesis of Thermophysical Characteristics of Nanofluids.” International Journal of Heat and Mass Transfer Vol. 54 No. 19 (2011): pp. 4410-4428.
[31] Mahjoob, Shadi, and Vafai, Kambiz. Analytical Characterization and Production of an Isothermal Surface for Biological and Electronics Applications. ASME Journal of Heat Transfer Vol. 131 (2009): pp. 052604-1-052604-12.
[32] Wu, Zhiyong, Caliot, Cyril, Flamant, Gilles, and Wang, Zhifeng. “Numerical Simulation of Convective Heat Transfer between Air Flow and Ceramic Foams to Optimise Volumetric Solar Air Receiver Performances.” International Journal of Heat and Mass Transfer Vol. 54 No. 7-8 (2011): pp. 1527-537.
[33] Lee, Dae-Young and Vafai, Kambiz. Analytical Characterization and Conceptual Assessment of Solid and Fluid Temperature Differentials in Porous Media. International Journal of Heat and Mass Transfer Vol. 42 No. 3 (1999): pp. 423-435.
[34] Pak, Bock C. and Cho, Young I.—Hydrodynamic and Heat Transfer Study of Dispersed Fluids with Submicron Metallic Oxide Particles. Experimental Heat Transfer Vol. 11 (1998): pp. 151-170.
[35] Saleh, Rosari, Putra, Nandy, Wibowo, Romualdus E., Spetiadi, Wayan N., and Prakoso, Suhendro P.—Titanium Dioxide Nanofluids for Heat Transfer Applications. Experimental Thermal and Fluid Science Vol. 52 (2014): pp. 19-29.
[36] Albojamal, Ahmedand Vafai, Kambiz. “Analysis of Single Phase, Discrete and Mixture Models, in Predicting Nanofluid Transport.” International Journal of Heat and Mass Transfer Vol. 114 (2017): pp. 225-237.
[37] Calmidi, Varaprasad V. and Mahajan, Roop L. Forced Convection in High Porosity Metal Foams. Journal of Heat Transfer Vol. 122 No. 3 (2000): pp. 557-565.
[38] Calmidi, Varaprasad V.—Transport Phenomena in High Porosity Fibrous Metal Foam. PhD Thesis. University of Colorado, Boulder, Colo. 1998.
[39] Mahjoob, Shadi and Vafai, Kambiz. Analytical Characterization of Heat Transport through Biological Media Incorporating Hyperthermia Treatment.II International Journal of Heat and Mass Transfer Vol. 52 No. 5 (2009): pp. 1608-1618.
[40] Iasiello, Marcello, Cunsolo, Salvatore, Bianco, Nicola, Chiu, Wilson K. S., and Naso, Vincenzo. “Developing Thermal Flow in Open-cell Foams.” International Journal of Thermal Sciences Vol. 111 (2017): pp. 129-37.

NOMENCLATURE

| | |
|---|---|
| c | specific heat, J/kg K |
| d_{f} | filament diameter, m |
| Da | Darcy number |
| F | geometric function |
| h | convection heat transfer coefficient, |
| | W/m² K |
| k | thermal conductivity, W/m K |
| k_{eff} | effective thermal conductivity, W/m |
| | K |
| K | permeability, m² |
| P | pressure, Pa |
| q | heat flux, W/m² |
| qₛ | source heat flux, W/m² |
| T | temperature, K |
| u | velocity, m/s |
| v | velocity vector, m/s |
| y | vertical coordinate, m |
| Greek symbols | |
| ε | porosity |
| ρ | density, kg/m³ |
| μ | dynamic viscosity, kg/m s |
| ∪ | kinematic viscosity, m²/s |
| Λ | inertia parameter |
| Subscripts | |
| f | fluid |
| s | solid |
| b | bulk flow |
| w | wall |
| Symbol | |
| < > | “Local volume average” of a |
| | quantity |

TABLE 3
Effective Properties of the Studied Coolants [19-22]

| | ρ | c | k | μ |
|---|---|---|---|---|
| | (kg/m³) | (J/kg K) | (W/m K) | (kg/m s) |
| Water | 998.2 | 4182 | 0.6 | 0.001003 |
| 5% titanium dioxide in | 1157 | 4007.5 | 0.774 | 0.001394 |
| water nanofluid | | | | |

We claim:

1. A high efficiency heat management device for use with a component, comprising:
at least one porous filled channel configuration component or at least one foam filled channel configuration component, wherein the least one porous filled channel configuration component or at least one foam filled channel configuration component comprises a channel base and a surface;
at least one jet impingement of at least one coolant;
at least one jet inlet, wherein the at least one jet inlet directs the at least one jet impingement of a liquid or a gas onto the surface of the at least one porous filled channel configuration component or at least one foam filled channel configuration component; and
at least one coolant exit channel.

2. The high efficiency heat management device for use with a component of claim 1, wherein the at least one porous filled channel configuration component or at least one foam filled channel configuration component is at least partially filled.

3. The high efficiency heat management device for use with a component of claim 1, wherein the at least one porous filled channel configuration component or at least one foam filled channel configuration component is completely filled.

4. The high efficiency heat management device for use with a component of claim 1, wherein the at least one porous filled channel configuration component or at least one foam filled channel configuration component comprises a confined geometry.

5. The high efficiency heat management device for use with a component of claim 1, wherein the at least one porous filled channel configuration component or at least one foam filled channel configuration component comprises an unconfined geometry.

6. The high efficiency heat management device for use with a component of claim 1, wherein the at least one coolant comprises a liquid or a gas.

7. The high efficiency heat management device for use with a component of claim 6, wherein the at least one coolant comprises water, a nanofluid, or a combination thereof.

8. The high efficiency heat management device for use with a component of claim 1, wherein the at least one jet inlet comprises a shape, wherein the shape is square or rectangular.

9. The high efficiency heat management device for use with a component of claim 1, wherein the at least one jet inlet has a two-dimensional configuration or a three-dimensional configuration.

10. The high efficiency heat management device for use with a component of claim 1, wherein the at least one jet inlet has a vertical enclosure having a top, a bottom, and at least one side.

11. The high efficiency heat management device for use with a component of claim 1, wherein the at least one jet inlet has a tapered directional component coupled with the bottom of the vertical enclosure.

12. The high efficiency heat management device for use with a component of claim 1, further comprising at least one component having a high heat flux value, wherein the component has a top surface.

13. The high efficiency heat management device for use with a component of claim 12, wherein the channel base of the at least one porous filled channel configuration component or at least one foam filled channel configuration component is operationally near, coupled with, or connected to the top surface of the component.

14. A high efficiency heat management device for use with a component, comprises:
at least one porous filled channel configuration component or at least one foam filled channel configuration component, wherein the at least one porous filled channel configuration component or at least one foam filled channel configuration component comprises a channel base and a surface;
at least one jet impingement of at least one thermal management liquid or gas;
at least one jet inlet, wherein the at least one jet inlet directs the at least one jet impingement of a liquid or a gas onto the surface of the at least one porous filled channel configuration component or at least one foam filled channel configuration component; and
at least one thermal management liquid or gas exit channel.

15. The high efficiency heat management device for use with a component of claim 14, wherein the at least one porous filled channel configuration component or at least one foam filled channel configuration component is at least partially filled.

16. The high efficiency heat management device for use with a component of claim 14, wherein the at least one porous filled channel configuration component or at least one foam filled channel configuration component is completely filled.

17. The high efficiency heat management device for use with a component of claim 14, wherein the at least one thermal management liquid or gas comprises water, a nanofluid, or a combination thereof.

18. The high efficiency heat management device for use with a component of claim 14, wherein the at least one jet inlet comprises a shape, wherein the shape is square or rectangular.
